(19) United States
(12) Patent Application Publication
(10) Pub. No.: US 2018/0003866 A1
(43) Pub. Date: Jan. 4, 2018

(54) POLARIZING PLATE AND IMAGE DISPLAY DEVICE COMPRISING THE SAME

(71) Applicant: DONGWOO FINE-CHEM CO., LTD., Jeollabuk-do (KR)

(72) Inventors: Gi Hwan AHN, Chungcheongnam-do (KR); Jung Ku LIM, Chungcheongnam-do (KR)

(21) Appl. No.: 15/704,609

(22) Filed: Sep. 14, 2017

Related U.S. Application Data
(63) Continuation of application No. PCT/KR2016/000827, filed on Jan. 26, 2016.

(30) Foreign Application Priority Data
Mar. 16, 2015 (KR) 10-2015-0035770

(51) Int. Cl. G02B 5/02; B32B 27/30; G02B 1/14; B32B 7/12; G02B 5/30; H01L 51/52; G02F 1/1335

(52) U.S. Cl. CPC G02B 5/0242; B32B 7/12; B32B 27/306; B32B 27/308; G02B 5/3025; G02B 1/14; B32B 2307/412; B32B 2307/42; B32B 2309/105; G02F 1/133528; H01L 51/5281; B32B 2307/418

(57) ABSTRACT

A polarizing plater includes a polarizer, a protective film disposed on at least one surface of the polarizer, and a diffusing adhesive layer and a transparent adhesive layer interposed between the polarizer and the protective film. The diffusing adhesive layer includes a diffusing particle. The diffusing particle includes a first diffusing particle and a second diffusing particle which have different average diameters from each other.

### CROSS-REFERENCE TO RELATED APPLICATIONS

The present application is a continuation application to international application no. PCT/KR2016/000827, with an international filing date of Jan. 26, 2016, which claims the benefit of Korean Patent Application No. 10-2015-0035770 filed in the Korean Intellectual Property Office on Mar. 16, 2015, the entire contents of which are incorporated herein by reference.

### BACKGROUND

### 1. Field

The present invention relates to a polarizing plate and an image display device including the same. More particularly, the present invention relates to a polarizing plate having improved haze, reduced moire and enhanced visibility, and an image display device including the same.

### 2. Description of the Related Art

A polarizing plate is used in various display devices such as a liquid crystal display (LCD) device, an electroluminescent (EL) device, a plasma display panel (PDP) device, a field emission display (FED) device, an organic light emitting diode (OLED) device, etc. The polarizing plate includes a polarizer that is formed of a polyvinyl alcohol (PVA) film including an iodine-based compound or a dichroic polarizing material adsorbed and oriented thereon. A polarizer protective film is formed on one surface of the polarizer, and a polarizer protective film, an adhesive layer combined with a liquid crystal cell and a release film are sequentially formed on the other surface of the polarizer.

A triacetate cellulose (TAC) film is used as the polarizer protective film, however, a price of the TAC film is much higher than that of a conventional polymer film. Accordingly, relatively cheap polymer films such as a polyethylene terephthalate (PET) film may be used instead of the TAC film, and an aqueous adhesive including an aqueous solution of a PVA resin may be normally used to laminate the protective film. However, the protective film as mentioned above may cause a moire in an image display device to deteriorate an image quality.

For example, Korean Laid-Open Patent Publication NO. 2007-0109134 discloses that a back-light unit includes a protective layer containing diffusing particles under a base film of a prism sheet to suppress the moire. However, additional processes are required to increase a process cost, and a thickness of the back-light unit is excessively increased.

### SUMMARY

According to an aspect of the present invention, there is provided a polarizing plate having improved haze.

According to an aspect of the present invention, there is provided a polarizing plate capable of preventing a moire.

According to an aspect of the present invention, there is provided an image display device including the polarizing plate.

The above aspects of the present inventive concepts will be achieved by the following features or characteristics:

(1) A polarizing plate comprising a polarizer; a protective film disposed on at least one surface of the polarizer; and a diffusing adhesive layer and a transparent adhesive layer interposed between the polarizer and the protective film, wherein the diffusing adhesive layer includes a diffusing particle, the diffusing particle including a first diffusing particle and a second diffusing particle which have different average diameters from each other.

(2) The polarizing plate according to the above (1), wherein the diffusing adhesive layer is formed of a composition for the diffusing adhesive layer which includes an acryl-based copolymer.

(3) The polarizing plate according to the above (2), wherein a maximum difference (|n1−n2|) between a refractive index (n1) of the acryl-based copolymer and a refractive index (n2) of the diffusing particle is in a range from 0.02 to 0.2.

(4) The polarizing plate according to the above (1), wherein a thickness of the diffusing adhesive layer is in a range from 1 to 50 μm.

(5) The polarizing plate according to the above (1), wherein a ratio of the average diameter of the second diffusing particle relative to the average diameter of the first diffusing particle is in a range from 1.3 to 6.

(6) The polarizing plate according to the above (1), wherein a mixing weight ratio of the first diffusing particle and the second diffusing particle is in a range from 20:80 to 80:20.

(7) The polarizing plate according to the above (1), wherein a ratio of the average diameter of the second diffusing particle relative to the average diameter of the first diffusing particle is in a range from 1.3 to 6, wherein a mixing weight ratio of the first diffusing particle and the second diffusing particle is in a range from 40:60 to 60:40.

(8) The polarizing plate according to the above (1), wherein a refractive index of the transparent adhesive layer is in a range from 1.4 to 1.7.

(9) The polarizing plate according to the above (1), wherein the protective film includes a first protective layer and a second protective layer which are formed at both sides of the polarizer, wherein the diffusing adhesive layer and the transparent adhesive layer are interposed between the polarizer and the first protective film, further comprising an aqueous adhesive layer interposed between the polarizer and the second protective layer.

(10) An image display device comprising the polarizing plate according to any one of the above (1)-(9).

The polarizing plate according to the present inventive concepts may include a first diffusing particle and a second diffusing particle which may have different average diameters from each other so that a light diffusive property may be improved, and a haze may be also improved relatively to a case using a single-type diffusing particle in which a haze is in a range from 30 to 80%. Further, moire may be prevented, and thus visibility may be enhanced.

In the polarizing plate of the present inventive concepts, a diffusing adhesive layer and a transparent adhesive layer may be interposed between a polarizer and at least one protective film to improve visibility.

### BRIEF DESCRIPTION OF THE DRAWINGS

FIG. 1 is a schematic cross-sectional view illustrating a polarizing plate in accordance with an example embodiment of the present inventive concepts.

FIG. 2 is a schematic cross-sectional view illustrating a diffusing adhesive layer and an adhesive layer in accordance with an example embodiment of the present inventive concepts.

FIG. 3 is a schematic cross-sectional view illustrating a polarizing plate in accordance with an example embodiment of the present inventive concepts.

### DETAILED DESCRIPTIONS

According to the present inventive concepts, a polarizing plate includes a polarizer and a protective film disposed on at least one surface of the polarizer. A diffusing adhesive layer and a transparent adhesive layer are disposed between the polarizer and the at least one protective layer. The diffusing adhesive layer includes a first diffusing particle and a second diffusing particle which have different average diameters from each other so that a light diffusive property may be increased, and a moire may be suppressed. An image display device including the polarizing plate is also provided.

Hereinafter, some exemplary embodiments of the present inventive concepts will be provided with accompanying drawings. However, these embodiments are only given for illustrating the present inventive concepts, and are not to be construed as limiting the scope of the present invention.

Polarizing Plate

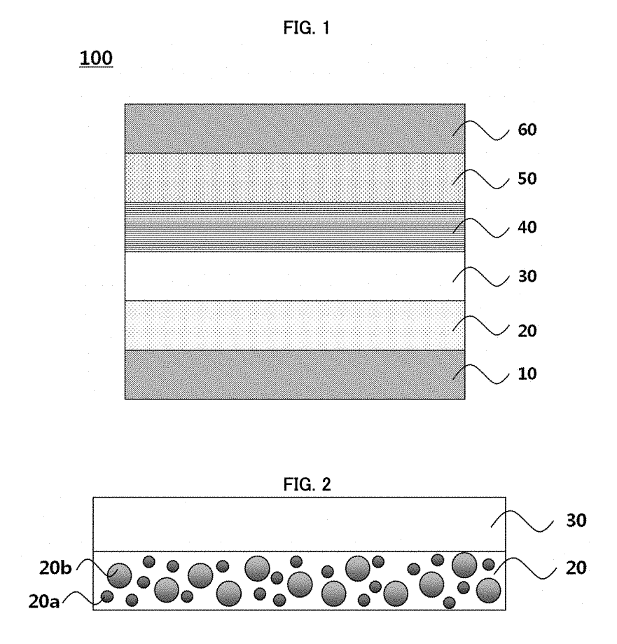

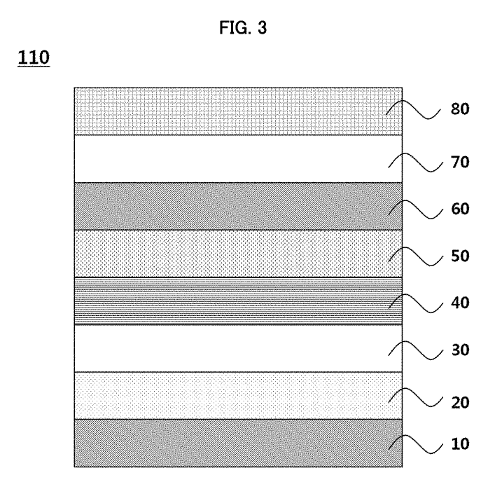

FIGS. 1 and 3 are schematic cross-sectional views illustrating a polarizing plate 100 and 110 in accordance with example embodiments of the present inventive concepts.

As illustrated in FIG. 1, the polarizing plate 100 may include a first protective film 10; a diffusing adhesive layer 20 formed on the first protective film 10; a transparent adhesive layer 30 formed on one surface of the diffusing adhesive layer 20; a polarizer 40 disposed on the diffusing adhesive layer 20; and a second protective film 60 disposed on the polarizer 40.

First and Second Protective Films

The polarizing plate 100 of the present inventive concepts may include a protective film disposed at least one surface of a polarizer. For example, the polarizing plate 100 may include the first protective film 10 and the second protective film 60 on both sides of the polarizer 40. Alternatively, the protective film may be formed on only one side of the polarizer 40.

The protective film may include any film having enhanced transparency, mechanical strength, thermal stability, moisture-shielding property, isotropic property, or the like. For example, the protective film may be formed of a thermoplastic resin including a polyester resin such as polyethylene terephthalate, polyethylene isophthalate, polyethylene naphthalate, polybutylene terephthalate, etc.; a cellulose resin such as diacetyl cellulose, triacetyl cellulose, etc.; a polycarbonate resin; an acryl resin such as polymethyl (meth)acrylate, polyethyl (meth)acrylate, etc.; a styrene resin such as polystyrene, an acrylonitrile-styrene copolymer, etc.; a polyolefin resin such as polyethylene, polypropylene, a cyclic polyolefin or a polyolefin having a norbornene structure, an ethylene-propylene copolymer, etc.; a vinyl chloride resin; a polyamide resin such as nylon, an aromatic polyimide; an imide resin; a polyether sulfonic resin; a sulfonic resin; a polyether ketone resin; a polyphenylene sulfide resin; a vinylalcohol resin; a vinylidene chloride resin; a vinylbutyral resin; an allylate resin; a polyoxymethylene resin; an epoxy resin, or the like. Further, a film formed using a blend of at least one thermoplastic resin described above may be used. A film formed of a thermosetting resin based on (meth)acrylate, urethane, acrylic urethane, epoxy, silicon, etc., or a UV-curable resin may also be used.

The first protective film 10 and the second protective film 60 may be formed of substantially the same material or different material from each other. From an aspect of improving polarizing property and mechanical durability, the cellulose resin such as triacetyl cellulose may be preferably used.

Particularly, the first protective film 10 may preferably include a polyester-based film for a compatibility with a composition for the diffusing adhesive layer, and the second protective layer 60 may preferably include a cellulose-based film from an aspect of improving polarizing property and mechanical durability.

The thermoplastic resin of the protective film may be included in an amount of 50 to 100 weight percent (wt %), preferably, 50 to 99 wt %, more preferably, 60 to 98 wt %, and most preferably, 70 to 97 wt % based on a total weight of the protective film. If a content of the thermoplastic resin is less than 50 wt %, an inherent high transparency of the thermoplastic resin may not be sufficiently expressed.

At least one additive may be contained in the protective film. The additive may include, for example, a UV-absorber, an antioxidant, a lubricant, a plasticizer, a releasing agent, an anti-coloring agent, a flame retardant, a nucleating agent, an antistatic agent, a pigment, a colorant, or the like.

In an embodiment, the protective film may be subject to a surface treatment. The surface treatment may include a dry treatment such as a plasma treatment, a corona treatment, a primer treatment, etc., or a chemical treatment such as an alkalization including a saponification.

In an implementation, at least one of the protective films formed on both sides of the polarizer may have an additional optical function. For example, at least one of the protective films may include an optical compensation film which may have a liquid crystal compound or a polymer thereof aligned on a substrate, a reflective polarizing splitting film which may selectively transmit a type of polarized light and reflect an opposite type of the polarized light, an optical compensation film including a polycarbonate resin, an optical compensation film including a cyclo olefin polymer resin, a reflective film having a reflection property at a surface thereof, a transflective film having both transmission and reflection properties, etc. The protective film may include a laminate of at least two of the above-mentioned films.

Preferably, when the optical compensation film is used, the protective film which is formed away from a surface on which the surface-treatment is performed may be the optical compensation film. Specifically, the second protective film 60 may also serve as a retardation film, or a conventional retardation film may be formed on the second protective film 60.

In an implementation, a surface treatment layer such as a hard coating layer, an anti-reflective layer, an anti-glare coating layer, an antistatic layer, or the like, may be further formed on a surface of the first protective layer 10 which may not be in contact with the polarizer.

A thickness of each the first protective film 10 and the second protective film 60 may be in a range from 1 to 200 μm in consideration of strength, workability, formation of thin-layered structure, etc., preferably in a range from 5 to 100 μm.

Additionally, as illustrated in FIG. 3, the polarizing plate 110 may include an adhesive layer 70 and a releasing film 80 sequentially formed on the second protective layer 60.

The adhesive layer 70 may be formed for being attached to a liquid crystal cell, and may be formed of an acryl-based copolymer, a cross-linking agent, a silane coupling agent, etc.

The acryl-based copolymer, the cross-linking agent and the silane coupling agent the same as those included in a composition for the diffusing adhesive layer may be used.

The releasing film 80 may be configured to protect the adhesive layer, and may include a material widely known in the art. For example, the releasing film 80 may include a polyolefin-based film formed of polyethylene, polypropylene, poly-1-butene, poly-4-methyl-1pentene, an ethylene-propylene copolymer, an ethylene-1-butene copolymer, an ethylene-acetic acid vinyl copolymer, an ethylene-ethyl acrylate copolymer, an ethylene-vinyl alcohol copolymer, etc.; a polyester-based film formed of polyethylene terephthalate, polyethylene naphthalate, polybutylene terephthalate, etc.; polyacrylate; polystyrene; a polyamide-based film formed of nylon 6, a partially aromatic polyamide, etc.; a polyvinyl chloride film; a polyvinylidene chloride film; or a polycarbonate film, etc. The above-mentioned materials may be properly releasing-treated by a silicon-based releasing agent, a fluorine-based releasing agent or a silica powder.

Diffusing Adhesive Layer

The polarizing plate of the present inventive concepts may include the diffusing adhesive layer 20 and the transparent adhesive layer 30 interposed between the polarizer 40 and at least one protective film.

For example, if the protective films are disposed at both sides of the polarizer 40, the diffusing adhesive layer 20 may be interposed between the polarizer 40 and the first protective film 10. The diffusing adhesive layer 20 may be formed of a composition for the diffusing adhesive layer which may include a first diffusing particle and a second diffusing particle having different particle diameters from each other so that a light diffusing property of the polarizing plate may be remarkably enhanced.

The diffusing particles are mixed and dispersed in the composition for the diffusing adhesive layer to increase the light diffusing property. As illustrated in FIG. 2, the diffusing adhesive layer 20 may include the first diffusing particle 20a and the second diffusing particle 20b which may have different average diameters to improve the light diffusing property and a visibility.

The average diameter of the diffusing particle may be properly adjusted according to a thickness of the diffusing adhesive layer 20. For example, the average diameter of the diffusing particle may be in a range from 2 to 20 μm, preferably in a range from 2 to 12 μm, or from 4 to 12 μm.

To further improve the light diffusing property, a ratio of the average diameter of the second diffusing particle 20b relative to the average diameter of the first diffusing particle 20a may be in a range from 1.3 to 6.

In the composition for the diffusing adhesive layer, a mixing weight ratio of the first diffusing particle 20a and the second diffusing particle 20b may be in a range from 20:80 to 80:20, preferably in a range from 40:60 to 60:40. Within the above-mentioned range, the light diffusing property may be further enhanced.

In the composition for the diffusing adhesive layer according to example embodiments, the ratio of the average diameter of the second diffusing particle 20b relative to the average diameter of the first diffusing particle 20a may be in a range from 1.3 to 6, and the mixing weight ratio of the first diffusing particle 20a and the second diffusing particle 20b may be in a range from 40:60 to 60:40 to further improve the light diffusing property.

The composition for the diffusing adhesive layer may further include an acryl-based copolymer and a cross-linking agent to provide an adhesive property.

In the composition for the diffusing adhesive layer, a maximum value of a difference between a refractive index of the acryl-based copolymer (n1) and a refractive index of the diffusing particle (n2), (i.e., |n1−n2|) may be preferably in a range from 0.02 to 0.2, more preferably in a range from 0.02 to 0.16. If the maximum value of |n1−n2| is less than 0.02, an amount of the diffusing particle may be excessively increased relatively to the acryl-based copolymer to cause a reduction of an adhesive durability. If the maximum value of |n1−n2| exceeds 0.2, an amount of the diffusing particle may be reduced, however, the moire may not be sufficiently prevented.

For example, the diffusing particle may include silica, calcium carbonate, aluminum hydroxide, magnesium hydroxide, titanium oxide, an acryl-based resin such as a polymethylmethacrylate resin , a polystyrene resin, a styrene-acryl copolymer resin, a polyethylene resin, an epoxy resin, etc. Preferably, the acryl-based resin, the polystyrene resin and the styrene-acryl copolymer resin may be used to improve dispersion with respect to the acryl-based copolymer. More preferably, a polymethylmethacrylate resin may be used.

The diffusing particles may be in a powder form, and a dispersion stability may be degraded when being directly added to the acryl-based copolymer with a high viscosity. In this case, the diffusing particles may not be uniformly distributed in the acryl-based copolymer. Thus, preferably, the diffusing particles may be fully dispersed in a solvent, and then may be added in the composition for the diffusing adhesive layer. The solvent for dispersing the diffusing particles may not be specifically limited. For example, a solvent substantially the same as that used in a preparation of the acryl-based copolymer as described below may be used. In an implementation, acetate-based, benzene-based or ketone-based solvents such as ethyl acetate, toluene, xylene, methyl ethyl ketone may be used to obtain dispersion and solvent resistance of the diffusing particles.

An amount of the diffusing particle may be properly adjusted according to the thickness of the diffusing adhesive layer and the average diameter of the diffusing particle. For example, the amount of the diffusing particle may be in a range from 10 to 100 parts by weight based on 100 parts by weight of the acryl-based copolymer (a solid content). If the amount of the diffusing particle is less than 10 parts by weights, the light diffusing property may be degraded. If the amount of the diffusing particle exceeds 100 parts by weight, a whitening of the diffusing adhesive layer may be caused to result in a low transparency.

The acryl-based copolymer may be achieved by a (meth)acrylate monomer having a C1-12 alkyl group and a polymerizable monomer having a cross-linkable functional group. The term “(meth)acrylate” may indicate acrylate and/or methacrylate.

The (meth)acrylate monomer having the C1-12 alkyl group may include n-butyl (meth)acrylate, 2-butyl (meth)acrylate, t-butyl (meth)acrylate, 2-ethylhexyl (meth)acrylate, ethyl (meth)acrylate, methyl (meth)acrylate, n-propyl (meth)acrylate, isobutyl (meth)acrylate, isopropyl (meth)acrylate, pentyl (meth)acrylate, hexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate, n-tridecyl (meth)acrylate, n-tetradecyl (meth)acrylate, pentafluorooctylacrylate, 6-(1-naphthyloxy)-1-hexylacrylate, lauryl(meth)acrylate, etc. These may be used alone or in a combination thereof. Preferably, n-butyl acrylate, 2-ethylhexyl acrylate or a combination thereof may be used.

An amount and a mixing ratio of the (meth)acrylate monomer having the C1-12 alkyl group may not be specifically limited. For example, the (meth)acrylate monomer may be included in a range from 85 to 99.9 parts by weight based on 100 parts by weight of a solid content of an entire monomer, preferably in a range from 90 to 95 parts by weight. If the amount of the (meth)acrylate monomer is less than 85 parts by weight, a sufficient adhesion may not be achieved. If the amount of the (meth)acrylate monomer exceeds 99.9 parts by weight, a cohesiveness may be degraded.

The polymerizable monomer having the cross-linkable functional group may be included to improve cohesiveness and adhesion of the composition and provide durability and cutting property. For example, the polymerizable monomer having the cross-linkable functional group may include a monomer containing a carboxyl group, a monomer containing a hydroxyl group, a monomer containing an amide group, a monomer containing a tertiary amine group, a monomer containing a sulfonate group, a monomer containing a phosphate group, a monomer containing a cyano group, a vinyl ester compound, an aromatic vinyl compound, a monomer containing an acid anhydride group, a monomer containing an epoxy group, a monomer containing an ether group, etc. These may be used alone or in a combination thereof. Preferably, the monomer may not include an acrylic acid for preventing a corrosion.

An amount and a mixing ratio of the polymerizable monomer having the cross-linkable functional group may not be specifically limited. For example, the polymerizable monomer may be included in a range from 0.1 to 15 parts by weight based on 100 parts by weight of a solid content of an entire monomer, preferably in a range from 0.5 to 8 parts by weight. If the amount of the polymerizable monomer is less than 0.1 parts by weight, the cohesiveness and durability of the adhesive composition may be deteriorated. If the amount of the polymerizable monomer exceeds 15 parts by weight, the adhesion and durability may be also deteriorated due to a high gel fraction.

The acryl-based copolymer may include an additional polymerizable monomer other than the above-mentioned monomers. The additional polymerizable monomer may be included in an amount which may not deteriorate the adhesion of the adhesive composition, e.g., in a range of 10 weight percent or less based on a total amount of the monomer.

The acryl-based copolymer may be prepared by a method commonly used in the related art, e.g., a bulk polymerization, a solution polymerization, an emulsion polymerization or a suspension polymerization. Preferably, the solution polymerization may be used. A solvent, an initiator, a chain transfer agent for controlling a molecular weight, etc., may be also used in the polymerization.

A weight average molecular weight (Mw) (based on polystyrene) of the acryl-based copolymer measured by a gel permeation chromatography (GPC) may be preferably in a range from 50,000 to 2,000,000, more preferably in a range from about 100,000 to about 1,800,000. If the molecular weight is less than 50,000, a cohesiveness between the copolymers may be insufficient to degrade adhesion durability. If the molecular weight exceeds 2,000,000, a large amount of a dilution solvent may be needed to obtain a coating convenience.

A refractive index of the acryl-based copolymer may be in a range from 1.4 to 1.7.

The cross-linking agent may be used to induce a crosslinking of the acryl-based copolymer and increase the cohesiveness. For example, an isocyanate-based compound, an epoxy-based compound, a melamine-based compound, an aziridine-based compound, or the like, may be used as the cross-linking agent. These may be used alone or in a combination thereof.

An amount of the cross-linking agent may not be specifically limited. For example, the cross-linking agent may be included in an amount from 0.1 to 15 parts by weight based on 100 parts by weight of a solid content of the acryl-based copolymer, preferably in a range from 0.1 to 5 parts by weight. If the amount of the cross-linking agent is less than 0.1 parts by weight, cohesiveness, adhesion durability and cutting property may be degraded due to an insufficient cross-linking degree. If the amount of the cross-linking agent exceeds 15 parts by weight, a residual stress may not be sufficiently relieved due to an excessive cross-linking.

The composition for the diffusing adhesive layer may further include a silane coupling agent.

The silane coupling agent may be covalently boned to a polar group on a surface of an object to enhance adhesion.

The silane coupling agent may contain a functional group such as an amino group, an epoxy group, an acetoacetyl group, a polyalkyleneglycol group, an acryl group, an alkyl group, etc. For example, the silane coupling agent may include vinyl trimethoxy silane, vinyl triethoxy silane, vinyl tris(2-methoxyethoxy) silane, N-(2-aminoethyl)-3-aminopropylmethyl dimethoxy silane, N-(2-aminoethyl)-3-aminopropyl trimethoxy silane, 3-aminopropyl triethoxy silane, 3-glycidoxy propyl trimethoxy silane, 3-glycidoxy propylmethyl dimethoxy silane, 2-(3,4-epoxycyclohexyl)ethyl trimethoxy silane, 3-chloropropyl dimethoxysilane, 3-chloropropyl trimethoxy silane, methacryloxy propyl trimethoxy silane, 3-mercaptopropyl trimethoxy silane, 3-glycidoxy propyl triethoxy silane, 3-glycidoxy propyl dimethoxymethyl silane, 3-glycidoxy propyl ethoxydimethyl silane, etc. These may be used alone or in a combination thereof.

An amount of the silane coupling agent may not be specifically limited. For example, the silane coupling agent may be included in an amount from 0.1 to 2 parts by weight based on 100 parts by weight of a solid content of the acryl-based copolymer, preferably in a range from 0.1 to 0.5 parts by weight. If the amount of the silane coupling agent is less than 0.1 parts by weight, an adhesion to a substrate may be insufficient to cause a delamination in a high humidity and heat condition. If the amount of the silane coupling agent exceeds 2 parts by weight, a cohesiveness may be excessively increased to deteriorate adhesive properties and durability.

The composition for the diffusing adhesive layer of the present inventive concepts may further include an additive such as an anti-oxidant, an anti-corrosion agent, a defoaming agent, a filler, an antistatic agent, etc., without departing from the spirit of the present inventive concepts.

A thickness of the diffusing adhesive layer 20 may be adjusted in consideration of the adhesion thereof. Preferably, the thickness of the diffusing adhesive layer 20 may be in a range from 1 to 50 μm, more preferably in a range from 1 to 30 μm.

Transparent Adhesive Layer

According to example embodiments, the polarizing plate 100 may include the polarizer 40, and the diffusing adhesive layer 20 and the transparent adhesive layer 30 interposed between the polarizer 40 and at least one protective film. The transparent adhesive layer 30 may be in contact with one surface of the diffusing adhesive layer 20. As illustrated in FIG. 2, the transparent adhesive layer 30 may not include diffusing particles, and may be formed on at least one surface of the diffusing adhesive layer 20 to prevent a reduction of transmittance.

A refractive index of the transparent adhesive layer 30 may be in a range from 1.4 to 1.7. Within the above range, transmittance may be improved

The transparent adhesive layer 30 may be formed of an adhesive composition commonly used in the related art. For example, the adhesive composition for the transparent adhesive layer 30 may include an acryl-based copolymer and a cross-linking agent substantially the same or similar to those for the diffusing adhesive layer 20.

A thickness of the transparent adhesive layer 30 may be adjusted in consideration of the adhesion thereof. Preferably, the thickness of the transparent adhesive layer 30 may be in a range from 1 to 50 μm, more preferably in a range from 1 to 30 μm.

Polarizer

The polarizer 40 may include an optical film by which a natural incident light may be converted into a single polarized state (a linearly polarized state), and may include a stretched polyvinyl alcohol resin film on which a dichroic dye is adsorbed and oriented.

The polyvinyl alcohol resin film may be prepared by a saponification of a polyvinyl acetate resin. The polyvinyl acetate resin may include polyvinyl acetate as a homopolymer of vinyl acetate, a copolymer of vinyl acetate and other monomers copolymerizable therewith. The monomer copolymerizable with vinyl acetate may include, for example, an unsaturated carboxylic acid monomer, an unsaturated sulfonic acid monomer, an olefin monomer, a vinyl ether monomer, an ammonium group-containing acrylamide monomers, or the like. The polyvinyl alcohol resin may include a modified resin, for example, aldehyde-modified polyvinylformal, polyvinylacetal, or the like. A saponification value of the polyvinyl alcohol resin may range from 85 to 100 mol %, preferably 98 mol % or more. A polymerization degree of the polyvinyl alcohol resin may range from 1,000 to 10,000, preferably from 1,500 to 5,000.

The above-mentioned polyvinyl alcohol resin may be formed into a raw film of the polarizer using a method widely known in the related art. For example, a thickness of the raw film may be in a range from 10 to 150 μm.

The polarizer may be prepared by continuously performing uniaxial stretching of the polyvinyl alcohol resin film, dyeing and adsorbing with a dichroic agent, treating with a boric acid solution, washing and drying.

The uniaxial stretching of the polyvinylalcohol resin film may be performed before dyeing, simultaneously with dyeing or after dyeing. When the uniaxial stretching is performed after dyeing, the uniaxial stretching may be performed before the boric acid solution treatment or during the boric acid solution treatment. The uniaxial stretching may be performed in a plurality of steps. The uniaxial stretching may be performed using rolls of different peripheral speeds or a thermal roll. The uniaxial stretching may include a dry stretching performed in an atmosphere, or a wet stretching performed by swelling with a solvent. A stretching ratio may range from 3 to 8.

For example, the stretched polyvinyl alcohol resin film may be immersed in an aqueous solution containing the dichroic agent. The dichroic agent may include iodine or a dichroic dye. Preferably, the polyvinyl alcohol resin film may be immersed and swelled in water before dyeing.

When iodine is used as the dichroic agent, the polyvinyl alcohol resin film may be immersed in a dyeing aqueous solution containing iodine and potassium iodide. An amount of iodine in the dyeing solution may be in a range from 0.01 to 1 part by weights based on 100 parts by weight of water (distilled water). An amount of potassium iodide may be in a range from 0.5 to 20 parts by weight based on 100 parts by weight of water. A temperature of the dyeing aqueous solution may be in a range from about 20 to 40° C., and an immersion time (dyeing time) may range from 20 to 1,800 seconds.

When the dichroic dye is used, the polyvinyl alcohol resin film may be immersed in a dyeing aqueous solution containing an aqueous dichroic dye. An amount of the dichroic dye may be in a range from 1×10⁻⁴ to 10 parts by weight based on 100 parts by weight of water, preferably from 1×10⁻³ to 10 parts by weight. The dyeing aqueous solution may further include an inorganic salt such as sodium sulfate as a dyeing auxiliary. A temperature of the dyeing aqueous solution may be in a range from about 20 to 80° C., and an immersion time (dyeing time) may range from 10 to 1,800 seconds.

The boric acid treatment may be performed by immersing the dyed polyvinyl alcohol resin film in an aqueous solution containing boric acid. An amount of boric acid in the aqueous solution may be in a range from 2 to 15 parts by weight based on 100 parts by weight of water, preferably from 5 to 12 parts by weight. When iodine is used as the dichroic agent, the aqueous solution containing boric acid may preferably include potassium iodide in an amount from 0.1 to 15 parts by eight based on 100 parts by weight of water, preferably from 5 to 12 parts by weight. A temperature of the aqueous solution containing boric acid may be 50° C. or more, preferably in a range from about 50 to 85° C., more preferably in a range from about 60 to 80° C. An immersion time may range from 60 to 1,200 seconds, preferably in a range from 150 to 600 seconds, more preferably in a range from 200 to 400 seconds.

The polyvinyl alcohol resin film may be washed and dried after the boric acid treatment. The washing process may include immersing of the boric acid treated polyvinyl alcohol resin film in water. A temperature of an immersing water may range from 5 to 40° C., and an immersion time may range from 1 to 120 seconds. The drying process may be performed using a heated air dryer or a far-infrared heater. A drying temperature may range from 30 to 100° C., preferably from 50 to 80° C. A drying time may range from 60 to 600 seconds, preferably from 120 to 600 seconds.

For example, a thickness of the polarizer 40 may be in a range from 5 to 40 μm.

Aqueous Adhesive Layer

In some embodiments, the polarizing plate 100 may include the protective films disposed at both ends of the polarizer. For example, the diffusing adhesive layer 20 and the transparent adhesive layer 30 may be interposed between the polarizer 40 and the first protective film 10, and the aqueous adhesive layer 50 may be interposed between the polarizer 40 and the second protective film 60.

An aqueous adhesive which may have an improve optical transparency and may have a resistance to a time-dependent yellowing may be used to form the aqueous adhesive layer 30 so that the polarizer 40 and the second protective film 60 may be sufficiently attached to each other. The aqueous adhesive may include a solution containing a polyvinyl alcohol-based resin and a cross-linking agent.

The polyvinyl alcohol-based resin may include, e.g., a polyvinyl alcohol resin, a polyvinyl alcohol resin having an acetoacetyl group or a mixture thereof. Preferably, the polyvinyl alcohol resin having the acetoacetyl group may be used to improve a durability of the polarizing plate due to a highly reactive functional group thereof.

For example, polyvinyl alcohol prepared by a saponification of poly vinyl acetate and its derivatives; a saponified copolymer of a monomer copolymerizable with vinyl acetate; and a modified polyvinyl alcohol prepared by acetalization, urethanization, etherification, graftication, and a phosphoric acid esterification of poly vinyl alcohol, etc., may be used. These may be used alone or in a combination thereof. The copolymerizable monomer may include unsaturated carboxylic acid such as (anhydrous)maleic acid, fumaric acid, crotonic acid, itaconic acid, (meth)acrylic acid and esters thereof, a-olefin such as ethylene and propylene, (meth)allylsulfonic acid (soda), sulfonic acid soda (monoalkyl maleate), disulfonic acid soda alkyl maleate, N-methylol acrylamide, acrylamide alkyl sulfonic acid alkali salt, N-vinyl pyrrolidone, N-vinyl pyrrolidone derivatives, or the like. An average polymerization degree of the polyvinyl alcohol-based resin may be, e.g., in a range from 100 to 5,000, preferably from 1,000 to 4,000 in consideration of an adhesive property. An average saponification degree of the polyvinyl alcohol-based resin may be in a range from 85 to 100 mol %, preferably from 90 to 100 mol %.

The polyvinyl alcohol resin having the acetoacetyl group may be obtained by reacting a polyvinyl alcohol-based resin and diketene. For example, the polyvinyl alcohol resin having the acetoacetyl group may be obtained by dispersing the polyvinyl alcohol-based resin in a solvent such as acetic acid and then adding diketene; dissolving the polyvinyl alcohol-based resin in a solvent such as dimethyl formamide or dioxane and then adding diketene; or directly contacting the polyvinyl alcohol-based resin with a diketene gas or a liquid diketene. A modification degree of the acetoacetyl group in the polyvinyl alcohol-based resin may be 0.1 mol % or more, preferably from 0.1 to 40 mol %, more preferably 1 to 20 mol %, most preferably from 2 to 7 mol %. If the modification degree of the acetoacetyl group is less than 0.1 mol %, a water resistance may be insufficient. If the modification degree of the acetoacetyl group exceeds 40 mol %, the water resistance may not be improved significantly.

Image Display Device

According to example embodiments of the present inventive concepts, an image display device including the polarizing plate and having improved visibility may be provided.

The image display device including the polarizing plate may include various display devices applicable in the related art such as a liquid crystal display device, an OLED display device, a flexible display device, etc.

Hereinafter, preferred embodiments are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### Synthesis Example 1: Synthesis of Acryl-Based Copolymer (A-1)

A 4-neck jacket reactor (1 L) were equipped with a stirrer, a thermometer, a reflux cooling tube, a dropping lot and a nitrogen gas inlet. The reactor was displaced by a nitrogen gas. 120 parts by weight of ethyl acetate, 98 parts by weight of n-butyl acrylate (n-BA), 0.5 parts by weight of acrylic acid (AA), and 1.4 parts by weight of 2-hydroxy ethyl acrylate were introduced in the reactor, and an external temperature of the reactor was raised to 50° C. A solution including 0.1 parts by weight of 2,2′-azobis isobutyronitrile (AIBN) fully dissolved in 10 parts by weight of ethyl acetate was dropped in the reactor. An external temperature of the jacket was maintained at 50° C., the reaction was additionally progressed for 5 hours, and then 90 parts by weight of ethyl acetate was slowly dropped for 1 hour using the dropping lot. Subsequently, the reaction was progressed for additional 5 hours at the same temperature. After finishing the reaction, an acryl-based copolymer solution which had a solid content of 20% was achieved by diluting with ethyl acetate. A weight average molecular weight (based on polystyrene) of the copolymer solution measured by GPC was about 1,500,000, and a refractive index was 1.47.

### Synthesis Example 2: Synthesis of Acryl-Based Copolymer (A-2)

A 4-neck jacket reactor (1 L) were equipped with a stirrer, a thermometer, a reflux cooling tube, a dropping lot and a nitrogen gas inlet. The reactor was displaced by a nitrogen gas. 120 parts by weight of ethyl acetate, 98 parts by weight of n-butyl acrylate (n-BA), 0.5 parts by weight of acrylic acid (AA), and 1.4 parts by weight of 2-hydroxy ethyl acrylate were introduced in the reactor, and an external temperature of the reactor was raised to 50° C. A solution including 0.1 parts by weight of 2,2′-azobis isobutyronitrile (AIBN) fully dissolved in 10 parts by weight of ethyl acetate was dropped in the reactor. An external temperature of the jacket was maintained at 50° C., the reaction was additionally progressed for 5 hours, and then 90 parts by weight of ethyl acetate was slowly dropped for 1 hour using the dropping lot. Subsequently, the reaction was progressed for additional 5 hours at the same temperature. After finishing the reaction, an acryl-based copolymer solution which had a solid content of 24% was achieved by diluting with ethyl acetate. A weight average molecular weight (based on polystyrene) of the copolymer solution measured by GPC was about 1,500,000, and a refractive index was 1.52.

### Synthesis Example 3: Synthesis of Acryl-Based Copolymer (A-3)

A 4-neck jacket reactor (1 L) were equipped with a stirrer, a thermometer, a reflux cooling tube, a dropping lot and a nitrogen gas inlet. The reactor was displaced by a nitrogen gas. 120 parts by weight of ethyl acetate, 98 parts by weight of n-butyl acrylate (n-BA), 0.5 parts by weight of acrylic acid (AA), and 1.4 parts by weight of 2-hydroxy ethyl acrylate were introduced in the reactor, and an external temperature of the reactor was raised to 50° C. A solution including 0.1 parts by weight of 2,2′-azobis isobutyronitrile (AIBN) fully dissolved in 10 parts by weight of ethyl acetate was dropped in the reactor. An external temperature of the jacket was maintained at 50° C., the reaction was additionally progressed for 5 hours, and then 90 parts by weight of ethyl acetate was slowly dropped for 1 hour using the dropping lot. Subsequently, the reaction was progressed for additional 5 hours at the same temperature. After finishing the reaction, an acryl-based copolymer solution which had a solid content of 33% was achieved by diluting with ethyl acetate. A weight average molecular weight (based on polystyrene) of the copolymer solution measured by GPC was about 1,500,000, and a refractive index was 1.55.

### EXAMPLES AND COMPARATIVE EXAMPLES

### Example 1

(1) Preparation of Composition for Diffusing Adhesive Layer

As described in Table 1 below, 100 parts by weight (based on a solid content) of the acryl-based copolymer of Synthesis Example 1, 0.8 parts by weight of trimethylolpropane-modified tolylene diisocyanate (Coronate L, Nippon Polyurethane Industry) as a cross-linking agent, 0.15 parts by weight of 3-glycidoxy propyl trimethoxy silane (KBM-403) as a silane coupling agent, and 40 parts by weight of polymethylmethacrylate particles (average diameter: 2 μm, spherical, refractive index: 1.49) as a first diffusing particle and 60 parts by weight of polymethylmethacrylate particles (average diameter: 8 μm, spherical, refractive index : 1.49) as a second diffusing particle, a total particle number of which 17,500,000 were input and dispersed in a toluene solvent. The solution was further diluted with toluene to obtain a composition for a diffusing adhesive layer.

(2) Preparation of Composition for Transparent Adhesive Layer

100 parts by weight (based on a solid content) of the acryl-based copolymer of Synthesis Example 1, 0.8 parts by weight of trimethylolpropane-modified tolylene diisocyanate (Coronate L, Nippon Polyurethane Industry) as a cross-linking agent and 0.15 parts by weight of 3-glycidoxy propyl trimethoxy silane (KBM-403) as a silane coupling agent were input and dispersed in a toluene solvent. The solution was further diluted with toluene to obtain a composition for a transparent adhesive layer.

(3) Fabrication of Polarizing Plate

The composition for the diffusing adhesive layer as prepared above was coated on a PET film as a first transparent protective film (25 cm×20 cm) using an applicator such that a thickness after drying was 10 μm, and dried for 3 minutes in a force circulation heated air dryer of 100° C. oven. A haze of the diffusing adhesive layer was measured using a hazemeter (HZ-1, Suga Test Instrument Co., Ltd.) based on a standard JIS K 7361-1 and Equation 1 below. The results are listed in Table 2 below.

Haze(%)=(Diffused Transmittance/Total Light Transmittance)×100 [Equation 1]

Next, the composition for the transparent adhesive composition was coated on the diffusing adhesive layer such that a thickness after drying was 20 μm, and dried. Subsequently, a silicon-treated PET releasing film was attached to obtain a diffusing adhesive transfer tape.

A PVA polarizer was interposed between the diffusing adhesive transfer tape and a TAC film as a second transparent protective film. The releasing film of the diffusing adhesive transfer tape was removed while laminating the diffusing adhesive layer on one surface of the polarizer. Simultaneously, the TAC film and an opposite surface of the polarizer were combined by injecting a PVA-based aqueous adhesive solution therebetween.

Subsequently, the composition for the transparent adhesive layer as prepared in (2) of Example 1 was coated on a silicon-treated PET releasing film (25 cm×20 cm) such that a thickness after drying was 20 μm, and dried for 3 minutes in a force circulation heated air dryer of 100° C. oven to form an adhesive sheet. The adhesive layer of the adhesive sheet was combined with the TAC film to form a polarizing plate.

### Examples 2 to 35

Polarizing plates were fabricated by a method substantially the same as that of Example 1 except for properties as described in Table 1.

A borosilicate glass was used as a diffusing particle having a refractive index of 1.56, and a calcium carbonate particle was used as a diffusing particle having a refractive index of 1.63.

### Comparative Example 1

Polarizing plates were fabricated by a method substantially the same as that of Example 1 except for properties as described in Table 1 and without coating the composition for the transparent adhesive layer on the diffusing adhesive layer during the fabrication of the diffusing adhesive transfer tape.

### Comparative Examples 2 and 3

Polarizing plates were fabricated by a method substantially the same as that of Example 1 except for properties as described in Table 1.

### Comparative Examples 4 and 5

Polarizing plates were fabricated by a method substantially the same as that of Example 1 except for properties as described in Table 1 and without coating the composition for the transparent adhesive layer on the diffusing adhesive layer during the fabrication of the diffusing adhesive transfer tape.

TABLE 1

| | | Composition for Diffusing Adhesive Layer | | | | | | |
|---|---|---|---|---|---|---|---|---|
| | Refractive Index | Refractive Index | | | | | | |
| | of Acryl-based | of Acryl-based | First | | Second | | First Diffusing | |
| | Copolymer in | Copolymer in | Diffusing | | Diffusing | | Particle:Second | Refractive |
| | Transparent | Diffusing | Particle | | Particle | | Diffusing | Index |
| Example | Adhesive | Adhesive | R.I | A.D | R.I | A.D | Particle (Mixing | Difference |
| No. | Layer (n3) | Layer (n1) | (n2) | (μm) | (n2) | (μm) | Weight Ratio) | (\|n1 − n2\|) |
| Example 1 | 1.47 | 1.47 | 1.49 | 2 | 1.49 | 8 | 4:6 | 0.02 |
| Example 2 | 1.47 | 1.47 | 1.49 | 2 | 1.49 | 10 | 5:5 | 0.02 |
| Example 3 | 1.47 | 1.47 | 1.49 | 2 | 1.49 | 12 | 6:4 | 0.02 |
| Example 4 | 1.47 | 1.47 | 1.49 | 2 | 1.49 | 12 | 3:7 | 0.02 |
| Example 5 | 1.47 | 1.47 | 1.49 | 2 | 1.49 | 14 | 6:4 | 0.02 |
| Example 6 | 1.47 | 1.52 | 1.56 | 4 | 1.56 | 8 | 4:6 | 0.04 |
| Example 7 | 1.47 | 1.52 | 1.56 | 4 | 1.56 | 10 | 5:5 | 0.04 |
| Example 8 | 1.47 | 1.52 | 1.56 | 4 | 1.56 | 12 | 6:4 | 0.04 |
| Example 9 | 1.47 | 1.52 | 1.56 | 4 | 1.56 | 12 | 3:7 | 0.04 |
| Example 10 | 1.47 | 1.55 | 1.63 | 6 | 1.63 | 8 | 4:6 | 0.08 |
| Example 11 | 1.47 | 1.55 | 1.63 | 6 | 1.63 | 10 | 5:5 | 0.08 |
| Example 12 | 1.47 | 1.55 | 1.63 | 6 | 1.63 | 12 | 6:4 | 0.08 |
| Example 13 | 1.47 | 1.55 | 1.63 | 6 | 1.63 | 12 | 3:7 | 0.08 |
| Example 14 | 1.52 | 1.47 | 1.56 | 6 | 1.56 | 8 | 5:5 | 0.09 |
| Example 15 | 1.52 | 1.47 | 1.56 | 6 | 1.56 | 10 | 6:4 | 0.09 |
| Example 16 | 1.52 | 1.47 | 1.56 | 6 | 1.56 | 12 | 4:6 | 0.09 |
| Example 17 | 1.52 | 1.47 | 1.56 | 6 | 1.56 | 12 | 3:7 | 0.09 |
| Example 18 | 1.52 | 1.52 | 1.63 | 2 | 1.63 | 8 | 5:5 | 0.11 |
| Example 19 | 1.52 | 1.52 | 1.63 | 2 | 1.63 | 10 | 6:4 | 0.11 |
| Example 20 | 1.52 | 1.52 | 1.63 | 2 | 1.63 | 12 | 4:6 | 0.11 |
| Example 21 | 1.52 | 1.52 | 1.63 | 2 | 1.63 | 12 | 3:7 | 0.11 |
| Example 22 | 1.52 | 1.52 | 1.63 | 2 | 1.63 | 14 | 4:6 | 0.11 |
| Example 23 | 1.52 | 1.55 | 1.49 | 4 | 1.49 | 8 | 5:5 | 0.06 |
| Example 24 | 1.52 | 1.55 | 1.49 | 4 | 1.49 | 10 | 6:4 | 0.06 |
| Example 25 | 1.52 | 1.55 | 1.49 | 4 | 1.49 | 12 | 4:6 | 0.06 |
| Example 26 | 1.55 | 1.47 | 1.63 | 4 | 1.63 | 8 | 6:4 | 0.16 |
| Example 27 | 1.55 | 1.47 | 1.63 | 4 | 1.63 | 10 | 4:6 | 0.16 |
| Example 28 | 1.55 | 1.47 | 1.63 | 2 | 1.63 | 12 | 5:5 | 0.16 |
| Example 29 | 1.55 | 1.47 | 1.63 | 4 | 1.63 | 8 | 3:7 | 0.16 |
| Example 30 | 1.55 | 1.52 | 1.49 | 6 | 1.49 | 8 | 6:4 | 0.03 |
| Example 31 | 1.55 | 1.52 | 1.49 | 6 | 1.49 | 10 | 4:6 | 0.03 |
| Example 32 | 1.55 | 1.52 | 1.49 | 6 | 1.49 | 12 | 5:5 | 0.03 |
| Example 33 | 1.55 | 1.52 | 1.49 | 6 | 1.49 | 12 | 3:7 | 0.03 |
| Example 34 | 1.55 | 1.55 | 1.56 | 2 | 1.56 | 10 | 4:6 | 0.01 |
| Example 35 | 1.55 | 1.55 | 1.56 | 2 | 1.56 | 12 | 5:5 | 0.01 |
| Comparative | — | 1.47 | 1.49 | 6 | — | — | — | 0.02 |
| Example 1 | | | | | | | | |
| Comparative | 1.47 | 1.52 | 1.56 | 4 | — | — | — | 0.04 |
| Example 2 | | | | | | | | |
| Comparative | 1.47 | 1.55 | 1.63 | 6 | — | — | — | 0.08 |
| Example 3 | | | | | | | | |
| Comparative | — | 1.55 | 1.56 | 2 | 1.56 | 4 | 8:2 | 0.01 |
| Example 4 | | | | | | | | |
| Comparative | — | 1.52 | 1.49 | 6 | 1.49 | 8 | 7:3 | 0.03 |
| Example 5 | | | | | | | | |

(R.I: Refractive Index, A.D: Average Diameter)

### Experimental Example

The PET releasing films were detached from the polarizing plates of Examples and Comparative Examples. The exposed adhesive layer and glass were attached, and then a following experiment was performed. The results are listed in Table 2 below.

(1) Evaluation of Moire

The polarizing plate as fabricated above was combined as a lower polarizing plate of a liquid crystal cell. A normal polarizing plate without a diffusing adhesive layer was combined as an upper polarizing plate of the liquid crystal cell. The liquid crystal cell was mounted on a prism sheet of a backlight unit in which a reflective plate, a light source, a diffusing plate and the prism sheet were sequentially stacked. An intensity of moire from the prism sheet was visually observed and evaluated based on the following standard.

⊚: Moire was not observed at all.

◯: Moire was slightly observed.

Δ: Moire was partially observed.

X: Moire was significantly observed.

XX: Moire was clearly observed.

TABLE 2

| | Tt | Td | Tp | | |
|---|---|---|---|---|---|
| | (Total Light | (Diffused | (Parallel Light | | |
| Example | Transmit- | Transmit- | Transmit- | Haze | |
| No. | tance) (%) | tance) (%) | tance) (%) | (%) | Moire |
| Example 1 | 73.3 | 72.13 | 1.17 | 98.4 | ⊚ |
| Example 2 | 52.1 | 51.52 | 0.58 | 98.89 | ⊚ |
| Example 3 | 40.04 | 39.64 | 0.4 | 99 | ⊚ |
| Example 4 | 16.2 | 16.02 | 0.18 | 98.9 | ⊚ |
| Example 5 | 19.8 | 19.6 | 0.2 | 98.9 | ⊚ |
| Example 6 | 69.57 | 68.5 | 1.07 | 98.46 | ⊚ |
| Example 7 | 60.14 | 59.36 | 0.78 | 98.7 | ⊚ |
| Example 8 | 58.4 | 57.66 | 0.74 | 98.73 | ⊚ |
| Example 9 | 31.6 | 31.1 | 0.5 | 98.42 | ⊚ |
| Example 10 | 52.46 | 51.8 | 0.66 | 98.74 | ⊚ |
| Example 11 | 51.73 | 51.09 | 0.64 | 98.76 | ⊚ |
| Example 12 | 43.81 | 43.31 | 0.5 | 98.86 | ⊚ |
| Example 13 | 18.7 | 18.4 | 0.3 | 98.4 | ⊚ |
| Example 14 | 51.3 | 50.69 | 0.61 | 98.81 | ⊚ |
| Example 15 | 43.87 | 43.39 | 0.48 | 98.91 | ⊚ |
| Example 16 | 30.03 | 29.7 | 0.33 | 98.9 | ⊚ |
| Example 17 | 24.6 | 24.3 | 0.3 | 98.8 | ⊚ |
| Example 18 | 47.41 | 46.9 | 0.51 | 98.92 | ⊚ |
| Example 19 | 44.76 | 44.29 | 0.47 | 98.95 | ⊚ |
| Example 20 | 26.08 | 25.84 | 0.24 | 99.08 | ⊚ |
| Example 21 | 21.2 | 21 | 0.2 | 99.06 | ⊚ |
| Example 22 | 3.8 | 3.7 | 0.1 | 97.37 | ⊚ |
| Example 23 | 69.7 | 68.6 | 1.1 | 98.42 | ⊚ |
| Example 24 | 70.49 | 69.36 | 1.13 | 98.4 | ⊚ |
| Example 25 | 58.01 | 57.27 | 0.74 | 98.72 | ⊚ |
| Example 26 | 34.89 | 34.58 | 0.31 | 99.11 | ⊚ |
| Example 27 | 9.87 | 9.78 | 0.09 | 99.09 | ⊚ |
| Example 28 | 5.65 | 5.6 | 0.05 | 99.12 | ⊚ |
| Example 29 | 3.8 | 3.7 | 0.1 | 97.37 | ⊚ |
| Example 30 | 87.79 | 84.88 | 2.91 | 96.69 | ⊚ |
| Example 31 | 80.02 | 78.42 | 1.6 | 98 | ⊚ |
| Example 32 | 65.39 | 64.23 | 1.16 | 98.23 | ⊚ |
| Example 33 | 12.56 | 12.42 | 0.14 | 98.92 | ⊚ |
| Example 34 | 80.09 | 78.34 | 1.75 | 97.81 | ⊚ |
| Example 35 | 65.97 | 65.04 | 0.93 | 98.59 | ⊚ |
| Comparative | 91.73 | 80.4 | 11.33 | 87.65 | Δ |
| Example 1 | | | | | |
| Comparative | 90.53 | 84.85 | 5.68 | 93.73 | ◯ |
| Example 2 | | | | | |
| Comparative | 64.83 | 58.23 | 6.6 | 89.82 | ◯ |
| Example 3 | | | | | |
| Comparative | 86.72 | 82.06 | 4.66 | 94.63 | ◯ |
| Example 4 | | | | | |
| Comparative | 88.77 | 85.52 | 3.25 | 96.33 | ◯ |
| Example 5 | | | | | |

Referring to Table 2 above, the polarizing plates of Examples had haze values and visibility greater than those of Comparative Examples without causing moire.

What is claimed is:

1. A polarizing plate, comprising:
a polarizer;
a protective film disposed on at least one surface of the polarizer;
a diffusing adhesive layer between the polarizer and the protective film, the diffusing adhesive layer comprising diffusing particles comprised of a first diffusing particle and a second diffusing particle which have different average diameters from each other; and
a transparent adhesive layer between the polarizer and the protective film.

2. The polarizing plate according to claim 1, wherein the diffusing adhesive layer is formed of a composition comprising an acryl-based copolymer.

3. The polarizing plate according to claim 2, wherein a maximum difference (|n1−n2|) between a refractive index (n1) of the acryl-based copolymer and a refractive index (n2) of the diffusing particles is in a range from 0.02 to 0.2.

4. The polarizing plate according to claim 1, wherein a thickness of the diffusing adhesive layer is in a range from 1 to 50 μm.

5. The polarizing plate according to claim 1, wherein a ratio of the average diameter of the second diffusing particle relative to the average diameter of the first diffusing particle is in a range from 1.3 to 6.

6. The polarizing plate according to claim 1, wherein a mixing weight ratio of the first diffusing particle and the second diffusing particle is in a range from 20:80 to 80:20.

7. The polarizing plate according to claim 1, wherein a ratio of the average diameter of the second diffusing particle relative to the average diameter of the first diffusing particle is in a range from 1.3 to 6,
wherein a mixing weight ratio of the first diffusing particle and the second diffusing particle is in a range from 40:60 to 60:40.

8. The polarizing plate according to claim 1, wherein a refractive index of the transparent adhesive layer is in a range from 1.4 to 1.7.

9. The polarizing plate according to claim 1, wherein the protective film includes a first protective layer and a second protective layer which are formed at both sides of the polarizer,
wherein the diffusing adhesive layer and the transparent adhesive layer are interposed between the polarizer and the first protective film,
further comprising an aqueous adhesive layer interposed between the polarizer and the second protective layer.

10. An image display device comprising the polarizing plate according to claims 1.

11. A polarizing plate, comprising:
a diffusing adhesive layer comprising diffusing particles comprised of a first diffusing particle and a second diffusing particle which have different average diameters from each other, the diffusing adhesive layer having a first surface and a second surface opposite to the first surface;
a transparent adhesive layer formed on the first surface of the diffusing adhesive layer;
a polarizer formed on the transparent adhesive layer;
at least one of a first protective film and a second protective film, the first protective film on the second surface of the diffusing adhesive layer, the second protective film formed on the polarizer.

12. The polarizing plate of claim 11, further comprising an aqueous adhesive layer,
wherein the second protective film is formed on the polarizer; and
the aqueous adhesive layer is interposed between the polarizer and the second protective film.

13. The polarizing plate of claim 12, wherein both the first protective film and the second protective film are present.

14. The polarizing plate of claim 11, wherein both the first protective film and the second protective film are present.

15. The polarizing plate of claim 11, further comprising an adhesive layer and a release film,
wherein the second protective film is formed on the polarizer; and
the adhesive layer and the release film are sequentially stacked on the second protective film.

16. The polarizing plate of claim 11, wherein the transparent adhesive layer is free from diffusing particles.

17. The polarizing plate of claim 11, wherein the diffusing adhesive layer is formed of a composition comprising an acryl-based copolymer.

18. The polarizing plate of claim 11, wherein a maximum difference (|n1−n2|) between a refractive index (n1) of the acryl-based copolymer and a refractive index (n2) of the diffusing particles is in a range from 0.02 to 0.2;
a ratio of the average diameter of the second diffusing particle relative to the average diameter of the first diffusing particle is in a range from 1.3 to 6; and
a mixing weight ratio of the first diffusing particle and the second diffusing particle is in a range from 20:80 to 80:20.
